(19) United States
(12) Patent Application Publication
(10) Pub. No.: US 2017/0237442 A1
(43) Pub. Date: Aug. 17, 2017

(54) CLOCK GENERATION CIRCUIT, INTERFACE CIRCUIT AND SEMICONDUCTOR SYSTEM USING THE SAME

(71) Applicant: SK hynix Inc., Icheon-si Gyeonggi-do (KR)

(72) Inventors: Kyung Hoon KIM, Icheon-si Gyeonggi-do (KR); Myeong Jae PARK, Icheon-si Gyeonggi-do (KR); Woo Yeol SHIN, Icheon-si Gyeonggi-do (KR); Sung Eun LEE, Icheon-si Gyeonggi-do (KR); Han Kyu CHI, Icheon-si Gyeonggi-do (KR); Jae Won HAN, Icheon-si Gyeonggi-do (KR)

(21) Appl. No.: 15/190,495

(22) Filed: Jun. 23, 2016

(30) Foreign Application Priority Data
Feb. 17, 2016 (KR) 10-2016-0018497

(51) Int. Cl. H03L 7/07; H03L 7/091; H03M 9/00; H03L 7/081

(52) U.S. Cl. CPC H03L 7/07; H03L 7/0816; H03L 7/091; H03M 9/00

(57) ABSTRACT

A clock generation circuit may be provided. The clock generation circuit may include a master DLL (Delay Locked Loop) circuit, a code divider and a slave DLL circuit. The master DLL may generate a phase pulse signal having a pulse width corresponding to one cycle of a clock signal, and may generate a delay control code corresponding to the phase pulse signal. The code divider may generate a divided delay control code corresponding to a predetermined time by dividing the delay control code. The slave DLL circuit may generate a delayed strobe signal by delaying a strobe signal according to the divided delay control code.

### CROSS-REFERENCES TO RELATED APPLICATION

The present application claims priority under 35 U.S.C. §119(a) to Korean application number 10-2016-0018497, filed on Feb. 17, 2016, in the Korean Intellectual Property Office, which is incorporated herein by reference in its entirety.

### BACKGROUND

1. Technical Field

Various embodiments may generally relate to a semiconductor device, and more particularly, to a clock generation circuit, an interface circuit and a semiconductor system using the same.

2. Related Art

A general semiconductor system may include a master device and a slave device. The slave device may be operated by the master device. The master device and the slave device may perform data communication while transmitting and receiving data. The semiconductor system may use a clock signal to transmit and receive data. When the master device and the slave device transmit data, the master device and the slave device may transmit the data in synchronization with the clock signal.

In general, the clock signal may be generated from a PLL (Phase Locked Loop) or DLL (Delay Locked Loop) circuit. The semiconductor system may generate a clock signal which has a phase synchronized with the data, through the PLL or DLL circuit.

### SUMMARY

In an embodiment, a clock generation circuit may be provided. The clock generation circuit may include a master DLL (Delay Locked Loop) circuit configured to generate a phase pulse signal having a pulse width corresponding to one cycle of a clock signal, and may generate a delay control code corresponding to the phase pulse signal. The clock generation circuit may include a code divider configured to generate a divided delay control code corresponding to a predetermined time by dividing the delay control code. The clock generation circuit may include a slave DLL circuit configured to generate a delayed strobe signal by delaying a strobe signal according to the divided delay control code.

In an embodiment, an interface circuit may be provided. The interface circuit may include a clock generation circuit configured to generate a phase pulse signal having a pulse width corresponding to one cycle of a clock signal, and may generate a delayed strobe signal by delaying a strobe signal by a predetermined time based on the phase pulse signal. The interface circuit may include a latch configured to latch data in synchronization with the delayed strobe signal. The interface circuit may include a data serializer/deserializer (SERDES) configured to sort and output an output of the latch.

In an embodiment, a semiconductor system may be provided. The semiconductor system may include a master device, and a slave device. The semiconductor system may include an interface circuit configured to receive a strobe signal and data which are outputted from the slave device, and may provide the strobe signal and data to the master device. The interface circuit may generate a phase pulse signal having a pulse width corresponding to one cycle of a clock signal based on a reset signal, and may set a delay amount corresponding to ¼ cycle of the clock signal based on the phase pulse signal.

### BRIEF DESCRIPTION OF THE DRAWINGS

FIG. 1 is a diagram illustrating a representation of an example of the configuration of a clock generation circuit according to an embodiment.

FIG. 2 is a diagram illustrating a representation of an example of the configuration of a master DLL circuit of FIG. 1.

FIG. 3 is a diagram illustrating a representation of an example of the configuration and operation of a fast detector of FIG. 2.

FIG. 4 is a diagram illustrating a representation of an example of the configuration of a semiconductor system according to an embodiment.

FIG. 5 is a diagram schematically illustrating representations of examples of the configurations of a clock generation circuit, an input/output circuit and a data SERDES in FIG. 4.

FIG. 6 is a diagram illustrating a representation of an example of the operation of the semiconductor system according to an embodiment.

FIG. 7 illustrates a representation of an example of a data processing system according to an embodiment. and

FIG. 8 is a diagram illustrating a representation of an example of the configuration of a memory system according to an embodiment.

### DETAILED DESCRIPTION

Hereinafter, a clock generation circuit, an interface circuit and a semiconductor system using the same according to the present disclosure will be described below with reference to the accompanying drawings through examples of the embodiments.

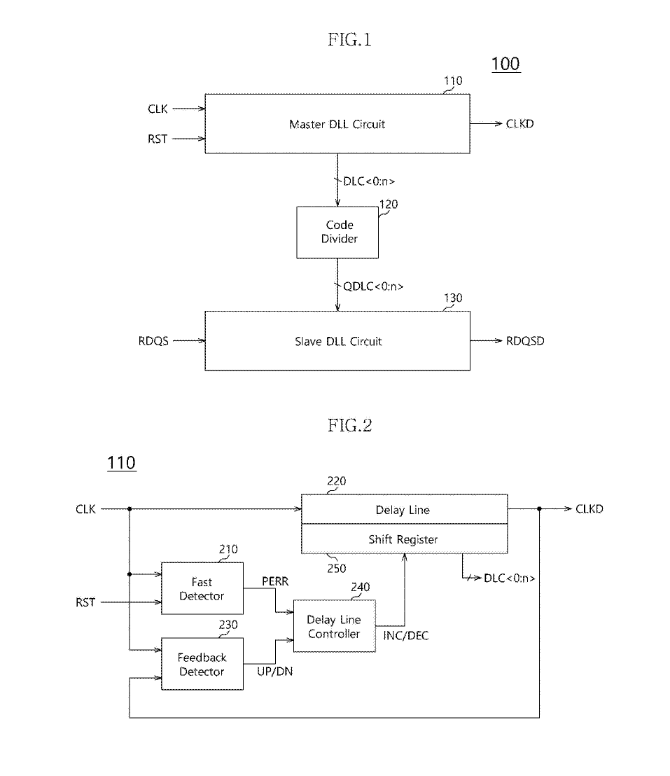

FIG. 1 is a diagram illustrating a representation of an example of the configuration of a clock generation circuit 100 according to an embodiment. Referring to FIG. 1, the clock generation circuit 100 may receive a clock signal CLK and a strobe signal RDQS. The clock generation circuit 100 may generate a pulse signal having a pulse width corresponding to one cycle of the clock signal CLK from the clock signal CLK, and set a delay amount corresponding to a predetermined time based on the pulse signal. The predetermined time may correspond to ¼ cycle of the clock signal CLK. The clock generation circuit 100 may include one or more DLL circuits for generating a plurality of clock signals. The clock generation circuit 100 may set the delay amount corresponding to the predetermined time based on the clock signal CLK in response to a reset signal RST in a semiconductor system including the clock generation circuit 100. The clock generation circuit 100 may generate a delayed strobe signal RDQSD by delaying the strobe signal RDQS by the predetermined time.

Referring to FIG. 1, the clock generation circuit 100 may include a master DLL circuit 110, a code divider 120 and a slave DLL circuit 130. The master DLL circuit 110 may receive the clock signal CLK, and generate a pulse signal corresponding to one cycle of the clock signal CLK from the clock signal CLK. The master DLL circuit 110 may generate a delay control code DLC<0:c> corresponding to the pulse signal. The master DLL circuit 110 may generate the pulse signal and the delay control code DLC<0:c> in response to a reset signal RST. The master DLL circuit 110 may receive the clock signal CLK and generate a delayed clock signal CLKD. The master DLL circuit 110 may compare the delayed clock signal CLKD to the clock signal CLK, and change a delay amount of the delayed clock signal CLKD. When the reset signal RST is enabled, the master DLL circuit 110 may not compare the delayed clock signal CLKD and the clock signal CLK, but generate the pulse signal and the delay control code DLC<0:n> from the clock signal CLK. The pulse signal will be described later.

The code divider 120 may receive the delay control code DLC<0:n>, and may generate a divided delay control code QDLC<0:n>. The code divider 120 may generate the divided delay control code QDLC<0:n> corresponding to a predetermined time. The predetermined time may correspond to ¼ cycle or 90-degree phase of the clock signal CLK. The code divider 120 may generate the divided delay control code QDLC<0:n> having a value corresponding to ¼ of the value of the delay control code DLC<0:n>. The delay control code DLC<0:n> may include a thermometer code, for example. In an embodiment, the code divider 120 may divide the thermometer code-type delay control code DLC<0:n>. In an embodiment, the code divider 120 may convert the thermometer code-type delay control code DLC<0:n> into binary code, and may generate the divided delay control code QDLC<0:n> by dividing the binary code.

The slave DLL circuit 130 may receive a strobe signal RDQS and generate a delayed strobe signal RDQSD. The slave DLL circuit 130 may generate the delayed strobe signal RDQSD by delaying the strobe signal RDQS according to the divided delay control code QDLC<0:n>. The slave DLL circuit 130 may generate the delayed strobe signal RDQSD by delaying the strobe signal RDQS by a time corresponding to ¼ cycle or 90-degree phase of the clock signal CLK.

When the reset signal RST is enabled, the master DLL circuit 110 may not compare the clock signal CLK to the delayed clock signal CLKD, but generate the pulse signal and the delay control code DLC<0:n> from the clock signal CLK. The master DLL circuit 110 and the code divider 120 may generate the divided delay control code QDLC<0:n> based on the pulse signal and the delay control code DLC<0:n>, and the slave DLL circuit 130 may set a delay amount corresponding to a predetermined time according to the divided delay control code QDLC<0:n>. Thus, the slave DLL circuit 130 may generate the delayed strobe signal RDQSD by delaying the strobe signal RDQS by the predetermined time.

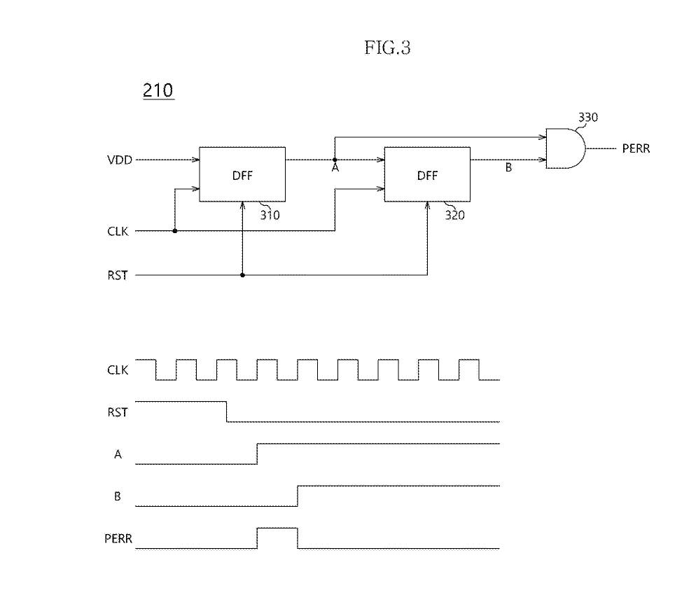

FIG. 2 is a diagram illustrating a representation of an example of the configuration of the master DLL circuit 110 of FIG. 1. Referring to FIG. 2, the master DLL circuit 110 may include a fast detector 210. The fast detector 210 may receive the clock signal CLK and the reset signal RST, and generate a phase pulse signal PERR. The phase pulse signal PERR may correspond to the pulse signal described with reference to FIG. 1. The fast detector 210 may generate the phase pulse signal PERR based on the clock signal CLK. When the reset signal RST is enabled, the fast detector 210 may generate the phase pulse signal PERR having a pulse width corresponding to one cycle of the clock signal CLK from the clock signal CLK, without a separate phase comparison operation.

Referring to FIG. 2, the master DLL circuit 110 may further include a delay line 220, a feedback detector 230, a delay line controller 240 and a shift register 250. The delay line 220 may generate the delayed clock signal CLKD by delaying the clock signal CLK.

The feedback detector 230 may receive the clock signal CLK and the delayed clock signal CLKD. The feedback detector 230 may receive the delay clock signal CLKD outputted from the delay line 220, and compare the delayed clock signal CLKD and the clock signal CLK. The feedback detector 230 may generate a phase detection signal UP/DN by comparing the phases of the clock signal CLK and the delayed clock signal CLKD. For example, the feedback detector 230 may generate an up signal UP of the phase detection signal when the phase of the clock signal CLK leads the phase of the delayed clock signal CLKD, and may generate a down signal DN of the phase detection signal when the phase of the clock signal CLK lags behind the phase of the delayed clock signal CLKD.

The delay line controller 240 may receive the phase pulse signal PERR and the phase detection signal UP/DN, and generate a delay line control signal INC/DEC. The delay line controller 240 may increase or decrease a code value of the shift register 250 in response to the phase detection signal UP/DN. For example, when the up signal UP is generated from the feedback detector 230, the delay line controller 240 may generate an increase signal INC to increase the code value of the shift register 250. For example, when the down signal DN is generated from the feedback detector 230, the delay line controller 240 may generate a decrease signal DEC to decrease the code value of the shift register 250. When the phase pulse signal PERR is received from the fast detector 210, the delay line controller 240 may generate the delay line control signal INC/DEC while the phase pulse signal PERR is enabled. For example, the delay line controller 240 may continuously generate the increase signal INC while the phase pulse signal PERR is enabled. Thus, the code value of the shift register 250 may be increased.

The code value of the shift register 250 may be adjusted in response to the delay line control signal INC/DEC, and the adjusted code value may be generated as the delay control code DLC<0:n>. The shift register 250 may set a delay amount of the delay line 220 according to the delay control code DLC<0:n>. When the phase pulse signal PERR is enabled, the shift register 250 may increase the value of the delay control code DLC<0:n> to a value corresponding to the pulse width of the phase pulse signal PERR in response to the delay line control signal INC/DEC. The shift register 250 may increase or decrease the value of the delay control code DLC<0:n> according to the delay line control signal INC/DEC which is generated based on the phase detection signal UP/DN. The shift register 250 may increase or decrease the delay amount of the delay line 220 according to the delay control code DLC<0:n>. The value of the delay control code DLC<0:n> of the shift register 250 and the delay amount of the delay line 220 may be set through a method disclosed in Korean Patent Laid-Open Publication No. 2012-0139627, but the present disclose is not limited thereto. Any shift registers and delay lines which are installed in a general DLL circuit may be applied to the present disclosure.

The master DLL circuit 110 may generate the delayed clock signal CLKD by delaying the clock signal CLK by a time corresponding to one cycle or 360-degree phase of the clock signal CLK. The master DLL circuit 110 may compare the clock signal CLK and the delayed clock signal CLKD, and set the delay amount of the delay line 220. When the reset signal RST is enabled, the master DLL circuit 110 may generate the phase pulse signal PERR through the fast detector 210, and fast set the delay amount of the delay line 220 without a feedback and comparison operation. Thus, the locking operation of the master DLL circuit 110 may be fast ended or ended quickly by the fast detector 210.

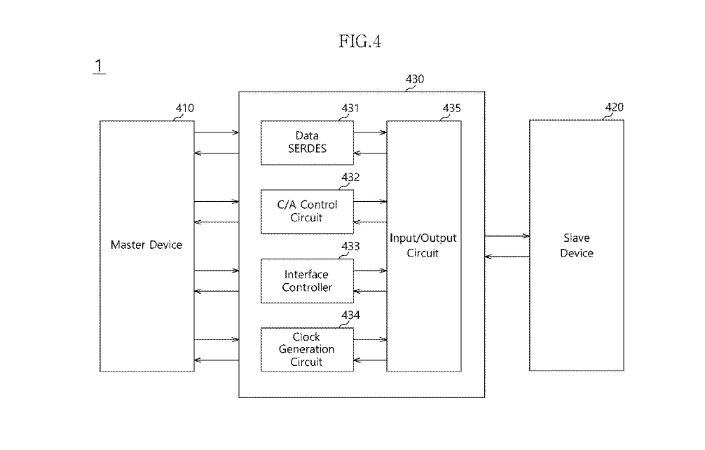

FIG. 3 is a diagram illustrating a representation of an example of the configuration and operation of the fast detector 210 of FIG. 2. Referring to FIG. 3, the fast detector 210 may include a first flip-flop 310, a second flip-flop 320 and a logic gate, for example but not limited to, an AND gate 330. The first and second flip-flops 310 and 320 may include D flip-flops, for example. The first flip-flop 310 may be reset in response to the reset signal RST, and output a supply voltage VDD in synchronization with the clock signal CLK. The second flip-flop 320 may be reset in response to the reset signal RST, and output the output A of the first flip-flop 310 in synchronization with the clock signal CLK. The AND gate 330 may generate the phase pulse signal PERR by performing an AND operation on the outputs A and B of the first and second flip-flops.

When the reset signal RST is enabled to a low level, the first and second flip-flops 310 and 320 may be reset. At a first rising edge of the clock signal CLK after the reset signal RST is enabled, the first flip-flop 310 may output the supply voltage VDD, and the output A of the first flip-flop may transition to a high level. The second flip-flop 320 may output the output A of the first flip-flop at the next rising edge of the clock signal CLK, and the output B of the second flip-flop may transition to a high level. A phase difference between the output A of the first flip-flop and the output B of the second flip-flop may correspond to one cycle of the clock signal CLK. The AND gate 330 may perform an AND operation on the outputs A and B of the first and second flip-flops, and may generate the phase pulse signal PERR having a pulse width corresponding to one cycle of the clock signal CLK.

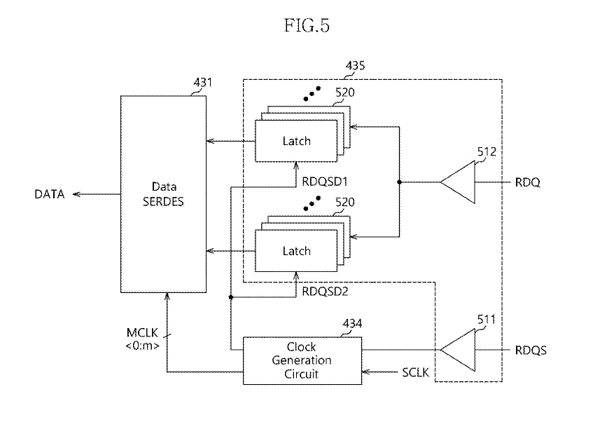

FIG. 4 is a diagram illustrating a representation of an example of the configuration of a semiconductor system 1 according to an embodiment. Referring to FIG. 4, the semiconductor system 1 may include a master device 410, a slave device 420 and an interface circuit 430. The master device 410 may perform data communication with the slave device 420. In order to transmit and receive data, the master device 410 may control the operation of the slave device 420. The interface circuit 430 may relay data communication between the master device 410 and the slave device 420. The interface circuit 430 may provide a signal transmitted from the master device 410 to the slave device 420, and provide a signal transmitted from the slave device 420 to the master device 410. Referring to FIG. 4, the interface circuit 430 may receive data and a strobe signal from the slave device 420, and provide the received data and strobe signal to the master device 410.

The master device 410 may include, for example but not limited to, a processor, and the processor may include a CPU (Central Processing Unit), GPU (Graphic Processing Unit), MMP (Multi-Media Processor) and a digital signal processor. Processor chips having various functions, such as an application processor (AP), may be combined and implemented in the form of a system on chip.

The slave device 420 may include modules capable of performing various functions, such as a system memory, a power controller, a communication module, a multimedia module and an input/output module. For example, the slave device 420 may include a memory device. The memory device may include, for example but not limited to, a volatile memory device such as SRAM (Static RAM), DRAM (Dynamic RAM) or SDRAM (Synchronous DRAM). Furthermore, the memory device may include one or more of nonvolatile memories such as ROM (Read Only Memory), PROM (Programmable ROM), EEPROM (Electrically Erase and Programmable ROM), EPROM (Electrically Programmable ROM), Flash memory, PRAM (Phase change RAM), MRAM (Magnetic RAM), RRAM (Resistive RAM) and FRAM (Ferroelectric RAM).

The interface circuit 430 may include, for example but not limited to, a data serializer/deserializer (SERDES) 431, a command address (C/A) control circuit 432, an interface controller 433, a clock generation circuit 434 and an input/output circuit 435. The data SERDES 531 may sort received data. The data SERDES 531 may convert serial data into parallel data or convert parallel data into serial data. For example, the master device 410 and the interface circuit 430 may perform serial data communication, and the interface circuit 430 and the slave device 420 may perform parallel data communication. The data SERDES 431 may convert data transmitted from the master device 410 into parallel data, and convert parallel data transmitted from the slave device 420 into serial data.

The C/A control circuit 432 may generate a command signal and address signal for accessing the slave device 420, based on a request transmitted from the master device 410. The interface controller 433 may control overall operations of the interface circuit 430. The clock generation circuit 434 may generate a delayed clock signal from the system clock signal. The clock generation circuit 434 may generate a delayed strobe signal by delaying a strobe signal. The clock generation circuit 100 of FIG. 1 may be applied as the clock generation circuit 434.

The input/output circuit 435 may include a plurality of pads, and transmit an output of the data SERDES 431, an output of the C/A control circuit 432, and an output of the clock generation circuit 434 to the slave device 420 or receive a signal from the slave device 420. The input/output circuit 435 may receive data and a strobe signal from the slave device 420. The input/output circuit 435 may latch data transmitted from the slave device 420 based on the strobe signal, and provide the latched data to the data SERDES 431. The input/output circuit 435 may latch the data in synchronization with the delayed strobe signal obtained by delaying the strobe signal by ¼ cycle or 90-degree phase of the system clock signal.

FIG. 5 is a diagram schematically illustrating representations of examples of the configurations of the clock generation circuit 434, the input/output circuit 435 and the data SERDES 431 in FIG. 4. The clock generation circuit 434 may receive the system clock signal SCLK, and receive the strobe signal RDQSD from the slave device 420. The strobe signal RDQS may be buffered through a buffer 511. The slave device 420 may provide data and a strobe signal to the master device during a read operation. Thus, the strobe signal RDQS may correspond to, for example, a read strobe signal. The clock generation circuit 434 may receive the strobe signal RDQS, and generate the delayed strobe signal by delaying the strobe signal RDQS by a time corresponding to ¼ cycle or 90-degree phase of the system clock signal SCLK. Referring to FIG. 5, the clock generation circuit 434 may generate first and second delayed strobe signals RDQSD1 and RDQSD2. The second delayed strobe signal RDQSD2 may correspond to a differential signal of the first delayed strobe signal RDQSD1. The first and second delayed strobe signals RDQSD1 and RDQSD2 may be used for a DDR (Double Data Rate) operation of the semiconductor system 1. The clock generation circuit 434 may generate a plurality of multi-phase clock signals MCLK<0:m> from the system clock signal SCLK.

The input/output circuit 435 may include a plurality of latches 520. The plurality of latches 520 may receive the data RDQ from the slave device 420. The data RDQ may be buffered through the buffer 512. The data RDQ may include, for example, read data. The plurality of latches 520 may latch the data RDQ in synchronization with the first and second delayed strobe signals RDQSD1 and RDQSD2. The data SERDES 431 may receive outputs of the plurality of latches 520, and convert the data latched by the latches 520 into serial data DATA in synchronization with the multi-phase clock signals MCLK<0:m>.

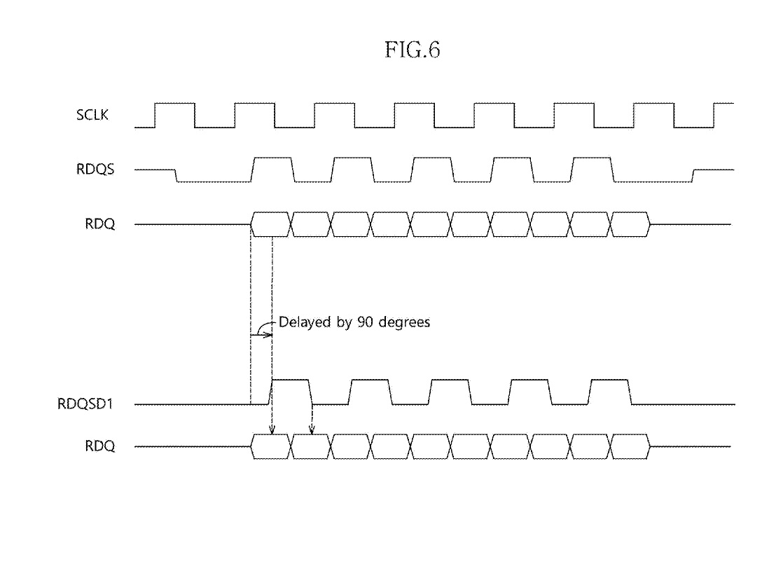

FIG. 6 is a diagram illustrating a representation of an example of the operation of the semiconductor system 1 according to an embodiment. Referring to FIGS. 1 to 6, the operation of the semiconductor system 1 according to a present embodiment will be described as follows. When the slave device 420 performs a read operation according to control of the master device 410, the interface circuit 430 may receive the data RDQ and the strobe signal RDQS from the slave device 420. The strobe signal RDQS may be transmitted in synchronization with the data RDQ. That is, the strobe signal RDQS may be edge-aligned with the data RDQ. The clock generation circuit 100 or 434 may receive the strobe signal RDQS, and generate the phase pulse signal PERR having a pulse width corresponding to one cycle of the system clock signal SCLK, or generate the delayed strobe signal RDQSD by delaying the strobe signal RDSQ by a time corresponding to ¼ cycle or 90-degree phase of the system clock signal SCLK, based on the phase pulse signal PERR. Since the duration or valid window of the data RDQ may correspond to ½ cycle or 180-degree phase of the system clock signal SCLK and the delayed strobe signal RDQSD is a signal delayed by 90 degrees from the strobe signal RDQS, rising and falling edges of the strobe signal RDQSD may be center-aligned with the data RDQ. The plurality of latches 520 may latch the data RDQ in synchronization with the delayed strobe signal RDQSD. At this time, since the delayed strobe signal RDQSD (i.e., RDQSD1) is center-aligned with the data RDQ, the plurality of latches 520 may correctly lath the levels of the data RDQ.

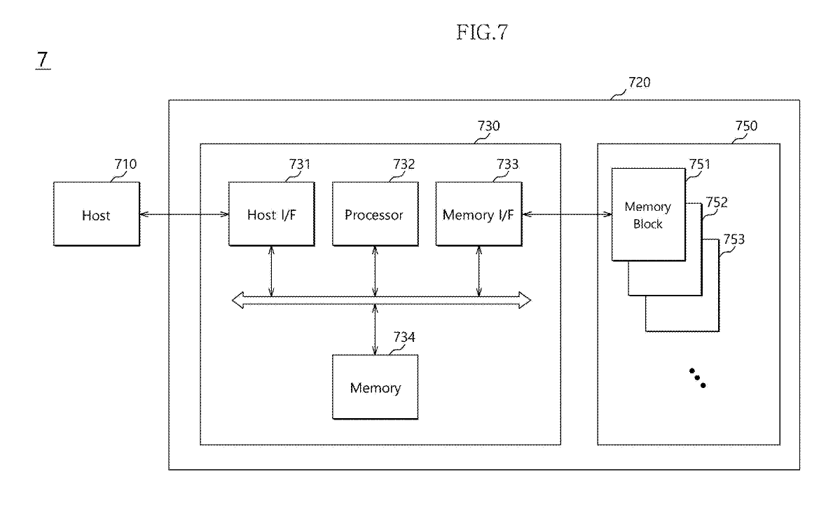

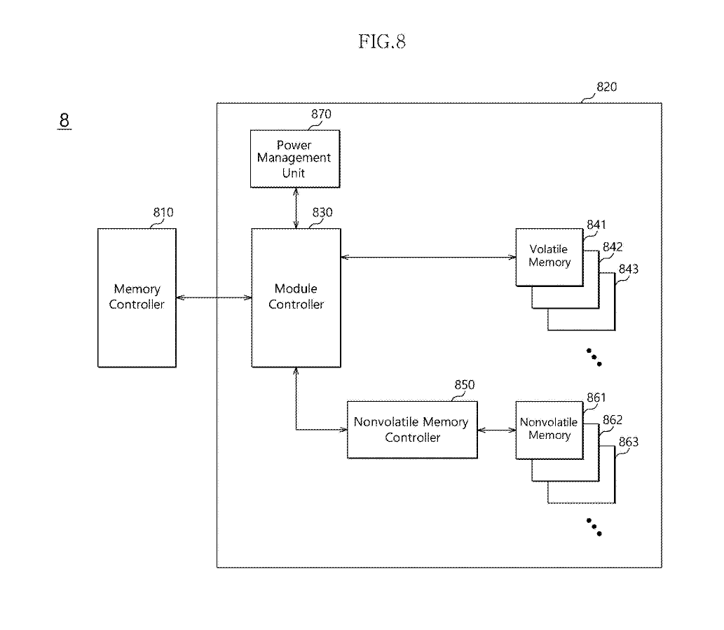

FIG. 7 illustrates a representation of an example of a data processing system 7 according to an embodiment. In an embodiment, a configuration of the data processing system 7 may be used without departing from the scope of the present disclosure. Referring to FIG. 7, the data processing system 7 may include a host 710 and a data storage device 720. The host 710 may include a portable electronic device such as, but not limited to, a mobile phone, MP3 player or laptop computer or an electronic device such as, but not limited to, a desktop computer, game player, TV or projector.

The data storage device 720 may operate in response to a request from the host 710, and store data accessed by the host 710. The data storage device 720 may be used as a main memory system or secondary memory system of the host 710. The data storage device 720 may be implemented as any one of various types of storage devices, according to the protocol of a host interface which is electrically coupled to the host 710. The data storage device 720 may be implemented as any one of, for example but not limited to, an SSD (Solid State Drive), MMC (Multimedia Card), eMMC (Embedded MMC), RS-MMC (reduced size-MMC), micro-MMC, SD (Secure Digital) card, mini-SD card, micro-SD card, USB (Universal Serial Bus) storage device, UFS (Universal Flash Storage) device, CF (Compact Flash) card, SM (Smart Media) card, and memory stick.

The data storage device 720 may be implemented as a volatile memory such as, but not limited to, DRAM (Dynamic Random Access Memory) and SRAM (Static RAM) or a nonvolatile memory device such as ROM (Read Only Memory), MROM (Mask ROM), PROM (Programmable ROM), EPROM (Erasable and Programmable ROM), EEPROM (Electrically Erasable and Programmable ROM), Ferroelectric RAM (FRAM), PRAM (Phase change RAM), MRAM (Magnetic RAM) and RRAM (Resistive RAM).

The data storage device 720 may include a memory device 750 for storing data accessed by the host 710 and a controller 730 for controlling the storage of data in the memory device 750. The controller 730 and the memory device 750 may be integrated in one semiconductor device. For example, the controller 730 and the memory device 750 may be integrated in one semiconductor device and constitute an SSD (Solid State Drive).

The controller 730 and the memory device 750 may be integrated in one semiconductor device and constitute a memory card. The controller 730 and the memory device 750 may be integrated in one semiconductor device and constitute a memory card such as, but not limited to, a PCMCIA (Personal Computer Memory Card International Association) card, CF card, SM card, memory stick, MMC, RS-MMC, micro-MMC, SD card, mini-SD card, micro-SD card, SDHC or USF device.

In an embodiment, the data storage device 720 may constitute, for example but not limited to, a computer, an UMPC (Ultra-Mobile PC), a workstation, a netbook computer, a PDA (Personal Digital Assistant), a portable computer, a web tablet, a tablet computer, a mobile phone, a portable phone, a smart phone, an e-book, a PMP (Personal Multimedia Player), a portable game player, a navigation device, a black box, a digital camera, a DMB (Digital Multimedia Broadcasting) player, a 3D (Three-Dimensional) television, a smart television, a digital audio recorder, a digital audio player, a digital image recorder, a digital image player, a digital video recorder, a digital video player, a storage device forming a data center, a device capable of transmitting and receiving information under a wireless environment, one of various electronic devices forming a home network, one of various electronic devices forming a computer network, one of various electronic devices forming a telematics network, an RFID (Radio-Frequency Identification) device or one of various parts forming a computing system.

The memory device 750 of the data storage device 720 may retain data stored therein when power supply is cut off. In particular, the memory device 750 may store data provided from the host 710 during a write operation, and provide data stored therein to the host 710 during a read operation. The memory device 750 may include a plurality of memory blocks 751 to 753. Each of the memory blocks 751 to 753 may include a plurality of pages. Each of the pages may include a plurality of memory cells to which a plurality of word lines WL are electrically coupled. The memory device 750 may include a nonvolatile memory device, for example, a flash memory. The flash memory may have, for example but not limited to, a 3D stack structure.

The controller 730 of the data storage device 720 may control the memory device 750 in response to a request from the host 710. The controller 730 may provide data read from the memory device 750 to the host 710, and store data provided from the host 710 in the memory device 750. For this operation, the controller 730 may control overall operations of the memory device 750, such as read, write, program and erase operations.

For example, the controller 730 may include a host interface (I/F) 731, a processor 732, a memory interface 733 and a memory 734. The host interface 731 may process a command and data which are provided from the host 710, and communicate with the host 710 through one or more of various interface protocols such as, but not limited to, USB, MMC, PCI-E (Peripheral Component Interconnect-Express), SAS (Serial Attached SCSI), SATA (Serial Attached Technology Attachment), PATA (Parallel Advanced Technology Attachment), SCSI (Small Computer System Interface), ESDI (Enhanced Small Disk Interface), and IDE (Integrated Drive Electronics).

The processor 732 may control a write or read operation for the memory device 750 and overall operations of the data storage device 720 in response to a write or read request from the host 710. The processor 732 may be drive firmware such as, but not limited to, FTL (Flash Translation Layer) in order to control the overall operations of the data storage device 720. The processor 732 may be implemented as a microprocessor or CPU. The processor 732 may include an ECC unit for detecting an error in data read from the memory device 750 during a read operation or perform an ECC function. The processor 732 may include a power management unit capable of managing power supply to components included in the controller 730 or perform a power management function.

The memory interface 733 may serve as an interface between the controller 730 and the memory device 750 such that the controller 730 can control the memory device 750 in response to a request from the host 710. The memory interface 733 may generate a control signal for the memory device 750, and process data under control of the processor 732. The memory device 750 may include a flash memory such as NAND flash memory, and the memory interface 733 may generate a control signal for the NAND flash memory or process data under control of the processor 732. The memory interface 733 may include the clock generation circuit 100 or 434 and the input/output circuit 435 which are illustrated in FIGS. 1 and 4, in order to perform data communication between the controller 730 and the memory device 750.

The memory 734 may serve as a working memory of the controller 730 and the data storage device 720, and store data for driving the controller 730 and the data storage device 720. When the controller 730 controls the operation of the memory device 750, the memory 734 may store data which are used by the memory device 750 and the controller 730 in order to perform a read, write, program or erase operation.

The memory 734 may be implemented with a volatile memory. The memory 734 may be implemented with SRAM or DRAM. The memory 734 may store data which are used by the host 710 and the memory device 750 during a read or write operation. In order to store data, the memory 734 may include a program memory, a data memory, a write buffer, a read buffer and a map buffer.

FIG. 8 is a diagram illustrating a representation of an example of the configuration of a memory system 8 according to an embodiment. The memory system 8 may include a memory controller 810 and a memory module 820. The memory module 820 may include an NVDIMM (Non Volatile Dual In Line Memory Module). The memory module 820 may include both of a volatile memory and a nonvolatile memory. The volatile memory may include DRAM and SRAM. The nonvolatile memory may include ROM, MROM, PROM, EPROM, EEPROM, FRAM, PRAM, MRAM and RRAM. In particular, the nonvolatile memory may include a flash memory, and the flash memory may have a 3D stack structure. The memory module 820 may include both the advantage of a volatile memory which has high data storage and output speed and the advantage of a nonvolatile memory which does not lose data even when power supply is suddenly cut off. The memory module 820 may perform an operation of backing up data stored in a volatile memory to a nonvolatile memory when power supply of the memory system 8 is not smoothly performed.

Referring to FIG. 8, the memory module 820 may include a module controller 830, volatile memories 841, 842 and 843, a nonvolatile memory controller 850, nonvolatile memories 861 to 863 and a power management unit 870. When power supply of the memory system 8 is normally performed, the module controller 830 may receive a control signal such as a command signal, address signal, clock signal or data from the memory controller 810, and provide the control signal to the volatile memories 841 to 843. The module controller 830 may buffer the data outputted from the volatile memories 841 to 843, and transmit the buffered data to the memory controller 810. The memory controller 810 may include an interface circuit for transmitting and receiving data to and from the module controller 830, and the interface circuit may include the clock generation circuit 100 or 434 and the input/output circuit 435 which are illustrated in FIGS. 1 and 4. The module controller 830 may include an interface circuit for transmitting and receiving data to and from the module controller 830, and the interface circuit may include the clock generation circuit 100 or 434 and the input/output circuit 435 which are illustrated in FIGS. 1 and 4.

When an abnormality occurs in the power supply of the memory system 8, for example, when the power supply is weakened or cut off, the power management unit 870 may detect the abnormality of the power supply, and supply emergency power to the components of the memory module 820. The power management unit 870 may include a capacitor with a large capacity for supplying the emergency power, for example, a supper cap.

When an abnormality of the power supply is detected by the power management unit 870, the module controller 830 may control the volatile memories 841 to 843 and the nonvolatile memory controller 850 to back up the data of the volatile memories 841 to 843 into the volatile memories 861 to 863. The module controller 830 may provide data outputted from the volatile memories 841 to 843 to the nonvolatile memory controller 850, and the nonvolatile memory controller 850 may store data provided from the module controller 830 in the nonvolatile memories 861 to 863. Then, when the power supply is normalized, the data backed up in the nonvolatile memories 861 to 863 may be stored in the volatile memories 841 to 843 to recover the data. The nonvolatile memory controller 850 may include an interface circuit for transmitting and receiving data to and from the nonvolatile memories 861 to 863, and the interface circuit may include the clock generation circuit 100 or 434 and the input/output circuit 435 which are illustrated in FIGS. 1 and 4.

While certain embodiments have been described above, it will be understood to those skilled in the art that the embodiments described are by way of example only. Accordingly, the semiconductor device described herein should not be limited based on the described embodiments. Rather, the semiconductor device described herein should only be limited in light of the claims that follow when taken in conjunction with the above description and accompanying drawings.

What is claimed is:

1. A clock generation circuit comprising:
a master DLL (Delay Locked Loop) circuit configured to generate a phase pulse signal having a pulse width corresponding to one cycle of a clock signal, and generate a delay control code corresponding to the phase pulse signal;
a code divider configured to generate a divided delay control code corresponding to a predetermined time by dividing the delay control code; and
a slave DLL circuit configured to generate a delayed strobe signal by delaying a strobe signal according to the divided delay control code.

2. The clock generation circuit according to claim 1, wherein the master DLL circuit comprises a fast detector configured to generate the phase pulse signal from the clock signal based on a reset signal.

3. The clock generation circuit according to claim 2, wherein the fast detector comprises:
a first flip-flop configured to output a supply voltage in synchronization with the clock signal;
a second flip-flop configured to output the output of the first flip-flop in synchronization with the clock signal; and
a logic gate configured to receive the outputs of the first and second flip-flops, perform an AND logic operation, and generate the phase pulse signal.

4. The clock generation circuit according to claim 2, wherein the master DLL circuit comprises:
a delay line configured to generate a delayed clock signal by delaying the clock signal;
a feedback detector configured to generate a phase detection signal by comparing the delayed clock signal and the clock signal;
a delay line controller configured to generate a delay line control signal based on the phase detection signal; and
a shift register configured to generate the delay control code based on the delay line control signal, and adjust a delay amount of the delay line.

5. The clock generation circuit according to claim 1, wherein the predetermined time corresponds to ¼ cycle of the clock signal.

6. The clock generation circuit according to claim 1, wherein the code divider generates the divided delay control code having a value corresponding to ¼ of the delay control code value.

7. The clock generation circuit according to claim 1, wherein the predetermined time corresponds to a 90-degree phase of the clock signal.

8. An interface circuit comprising:
a clock generation circuit configured to generate a phase pulse signal having a pulse width corresponding to one cycle of a clock signal, and generate a delayed strobe signal by delaying a strobe signal by a predetermined time based on the phase pulse signal;
a latch configured to latch data in synchronization with the delayed strobe signal; and
a data serializer/deserializer (SERDES) configured to sort and output an output of the latch.

9. The interface circuit according to claim 8, wherein the predetermined time corresponds to ¼ cycle of the clock signal.

10. The interface circuit according to claim 9, wherein rising and falling edges of the strobe signal is center-aligned with the data.

11. The interface circuit according to claim 8, wherein the clock generation circuit comprises:
a master DLL (Delay Locked Loop) circuit configured to generate the phase pulse signal and a delay control code corresponding to the phase pulse signal;
a code divider configured to generate a divided delay control code by dividing the delay control code; and
a slave DLL circuit configured to generate the delayed strobe signal by delaying the strobe signal based on the divided delay control code.

12. The interface circuit according to claim 11, wherein the master DLL circuit comprises a fast detector configured to generate the phase pulse signal from the clock signal based on a reset signal.

13. The interface circuit according to claim 12, wherein the fast detector comprises:
a first flip-flop configured to output a supply voltage in synchronization with the clock signal;
a second flip-flop configured to output the output of the first flip-flop in synchronization with the clock signal; and
a logic gate configured to receive the outputs of the first and second flip-flops, perform an AND logic operation, and generate the phase pulse signal.

14. The interface circuit according to claim 12, wherein the master DLL circuit comprises:
a delay line configured to generate a delayed clock signal by delaying the clock signal;
a feedback detector configured to generate a phase detection signal by comparing the delayed clock signal and the clock signal;
a delay line controller configured to generate a delay line control signal based on the phase detection signal; and
a shift register configured to generate the delay control code based on the delay line control signal, and adjust a delay amount of the delay line.

15. The interface circuit according to claim 11, wherein the code divider generates the divided delay control code having a value corresponding to ¼ of the delay control code value.

16. A semiconductor system comprising:
a master device;
a slave device; and
an interface circuit configured to receive a strobe signal and data which are outputted from the slave device, and provide the strobe signal and data to the master device,
wherein the interface circuit generates a phase pulse signal having a pulse width corresponding to one cycle of a clock signal based on a reset signal, and sets a delay amount corresponding to ¼ cycle of the clock signal based on the phase pulse signal.

17. The semiconductor system according to claim 16, wherein the clock generation circuit generates a delayed strobe signal by delaying the strobe signal by a delay amount corresponding to ¼ cycle of the clock signal.

18. The semiconductor system according to claim 17, wherein the interface circuit comprises a latch configured to latch the data in synchronization with the delayed strobe signal.

19. The semiconductor system according to claim 16, wherein the clock generation circuit comprises:
a master DLL (Delay Locked Loop) circuit configured to generate the phase pulse signal and a delay control code corresponding to the phase pulse signal based on the reset signal;
a code divider configured to generate a divided delay control code by dividing the delay control code; and
a slave DLL circuit configured to generate the delayed strobe signal by delaying the strobe signal according to the divided delay control code.

20. The semiconductor system according to claim 19, wherein the master DLL circuit comprises a fast detector configured to generate the phase pulse signal from the clock signal based on the reset signal.

21. The semiconductor system according to claim 20, wherein the master DLL circuit comprises:
a delay line configured to generate a delayed clock signal by delaying the clock signal;
a feedback detector configured to generate a phase detection signal by comparing the delayed clock signal and the clock signal;
a delay line controller configured to generate a delay line control signal based on the phase detection signal; and
a shift register configured to generate the delay control code based on the delay line control signal, and adjust a delay amount of the delay line.

22. The semiconductor system according to claim 19, wherein the code divider generates the divided delay control code having a value corresponding to ¼ of the delay control code value.

23. The semiconductor system according to claim 16, wherein rising and falling edges of the strobe signal is center-aligned with the data.
